(19) United States
(12) Patent Application Publication
(10) Pub. No.: US 2014/0168924 A1
(43) Pub. Date: Jun. 19, 2014

(54) BUTTON ASSEMBLY AND HANDHELD ELECTRONIC DEVICE

(71) Applicant: HTC CORPORATION, Taoyuan County (TW)

(72) Inventors: Kuan-Ku Kuo, Taoyuan County (TW); I-Cheng Chuang, Taoyuan County (TW); Yu-Jing Liao, Taoyuan County (TW)

(73) Assignee: HTC CORPORATION, Taoyuan County (TW)

(21) Appl. No.: 13/714,431

(22) Filed: Dec. 14, 2012

(51) Int. Cl. H01H 13/50; H05K 5/02

(52) U.S. Cl. CPC H01H 13/50; H05K 5/02
USPC 361/781; 361/679.01; 361/760; 200/341

(57) ABSTRACT

A button assembly suitable for being disposed at an opening of a housing of a handheld electronic device is provided. The button assembling includes a button, a signal-receiving-and-transmitting component and a switch. The button is movably disposed at the opening, and the button has a pressing portion exposed by the housing. The signal-receiving-and-transmitting component is disposed in the housing and corresponds to the pressing portion, wherein the signal-receiving-and-transmitting component is suitable for transmitting or receiving a wireless signal passing through the pressing portion. The switch is disposed in the housing and coupled to the button, so that the switch is adapted to be actuated by pressing the pressing portion of the button. A handheld electronic device including a body, a housing and a button assembly is also provided. The housing covers the body and has an opening. The button assembly is disposed at the opening.

### BACKGROUND OF THE INVENTION

1. Field of the Invention

The present invention generally relates to a button assembly, and particularly to a handheld electronic device using the button assembly.

2. Description of Related Art

Recently, with advancement of technologies, electronic devices including mobile phones, tablet computers, notebook computers, and smart phones, etc., have made progress for easy operation, powerful functionality, and embellished exterior design to provide users with more choices.

On a housing of an electronic product, a button is often disposed for controlling a switch, for example, power switch or volume switch of a speaker, located inside the electronic product. Therefore, the housing of the electronic product usually has a corresponding opening for disposing the button, so that the button is connected to the switch inside the electronic product and is exposed by the housing for a user to operate.

Apart from its own functions, the electronic product also enables the user to control other external devices by operating the electronic product through built-in program and a signal-receiving-and-transmitting component, so as to improve the practicability of the electronic product. When the signal-receiving-and-transmitting component is disposed inside the electronic product, the housing of the electronic product also needs to have corresponding opening for wireless signals to pass through. However, in order to increase the functions of the electronic product, excessive amount of openings are disposed on the housing of the electronic product which has negative influence on the aesthetic appearance of the electronic product.

### SUMMARY OF THE INVENTION

Accordingly, the present invention is directed to a button assembly suitable for a handheld electronic device with fewer openings

Further, the present invention is also directed to a handheld electronic device capable of reducing the amount of the openings of the housing thereof.

The present invention provides a button assembly suitable for being disposed at an opening of a housing of a handheld electronic device. The button assembling includes a button, a signal-receiving-and-transmitting component and a switch. The button is movably disposed at the opening, and the button has a pressing portion exposed by the housing. The signal-receiving-and-transmitting component is disposed in the housing and corresponds to the pressing portion, wherein the signal-receiving-and-transmitting component is suitable for transmitting or receiving a wireless signal passing through the pressing portion. The switch is disposed in the housing and coupled to the button, so that the switch is adapted to be actuated by pressing the pressing portion of the button.

The present invention further provides a handheld electronic device including a body, a housing and a button assembly. The housing covers the body and has an opening. The button assembly is disposed at the opening. The button assembling includes a button, a signal-receiving-and-transmitting component and a switch. The button is movably disposed at the opening, and the button has a pressing portion exposed by the housing. The signal-receiving-and-transmitting component is disposed in the housing and corresponds to the pressing portion, wherein the signal-receiving-and-transmitting component is suitable for transmitting or receiving a wireless signal passing through the pressing portion. The switch is disposed in the housing and coupled to the button, so that the switch is adapted to be actuated by pressing the pressing portion of the button.

According to an embodiment of the present invention, the signal-receiving-and-transmitting component includes an infrared-receiving-and-transmitting component.

According to an embodiment of the present invention, the button assembly further includes a first circuit board disposed in the housing, and the signal-receiving-and-transmitting component is disposed on a first surface of the first circuit board.

According to an embodiment of the present invention, the button has a containing space, the first circuit board is disposed in the containing space, and the first surface faces the pressing portion.

According to an embodiment of the present invention, the switch is disposed on a second surface of the first circuit board, the second surface is opposite to the first surface, and the button exposes the switch.

According to an embodiment of the present invention, the switch corresponds to a protrusion, the protrusion is disposed in the housing and faces the opening.

According to an embodiment of the present invention, the button assembly further includes a second circuit board disposed in the housing, the switch is disposed on a third surface of the second circuit board, and the third surface faces the button.

According to an embodiment of the present invention, the button assembly further includes a protrusion disposed on a surface of the button inside the housing and corresponding to the switch.

According to an embodiment of the present invention, the containing space is sealed. The first circuit board and the signal-receiving-and-transmitting component are disposed in the containing space.

According to an embodiment of the present invention, the button assembly further includes a waterproof material disposed at the opening and isolating the button and an inner space of the housing, the button and the switch are respectively located at two opposing sides of the waterproof material.

According to an embodiment of the present invention, the first circuit board is located outside the button. The signal-receiving-and-transmitting component and the switch are disposed on a first surface of the first circuit board.

According to an embodiment of the present invention, the button assembly further includes a protrusion disposed on a surface of the button inside the housing and corresponding to the switch.

Based on the description above, the present invention provides a button assembly and a handheld electronic device using the same, wherein the button is movably disposed at the opening. The signal-receiving-and-transmitting component and the switch are disposed inside the housing of the handheld electronic device, and the signal-receiving-and-transmitting component corresponds to a pressing portion of the button. The signal-receiving-and-transmitting component is suitable for transmitting or receiving a wireless signal passing through the pressing portion, and the switch is adapted to be actuated by pressing the pressing portion of the button. Accordingly, the button assembly is suitable for a handheld electronic device with fewer openings so as to reduce the amount of the openings located on the housing of the handheld electronic device.

Several exemplary embodiments accompanied with figures are described in detail below to further describe the invention in details.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic view illustrating a handheld electronic device according to an embodiment of the invention.

FIG. 2 is a partially enlarged view illustrating the handheld electronic device in FIG. 1.

FIG. 3 is a schematic view illustrating the button assembly in FIG. 1.

FIG. 4 is a partially enlarged view illustrating a handheld electronic device according to another embodiment of the present invention.

FIG. 5 is an exploded view illustrating the button in FIG. 4.

FIG. 6 is a schematic view illustrating the button in FIG. 5.

FIG. 7 is a partially enlarged view illustrating a handheld electronic device according to yet another embodiment of the present invention.

FIG. 8 is a schematic view illustrating the button assembly in FIG. 7.

### DETAILED DESCRIPTION OF DISCLOSED EXEMPLARY EMBODIMENTS

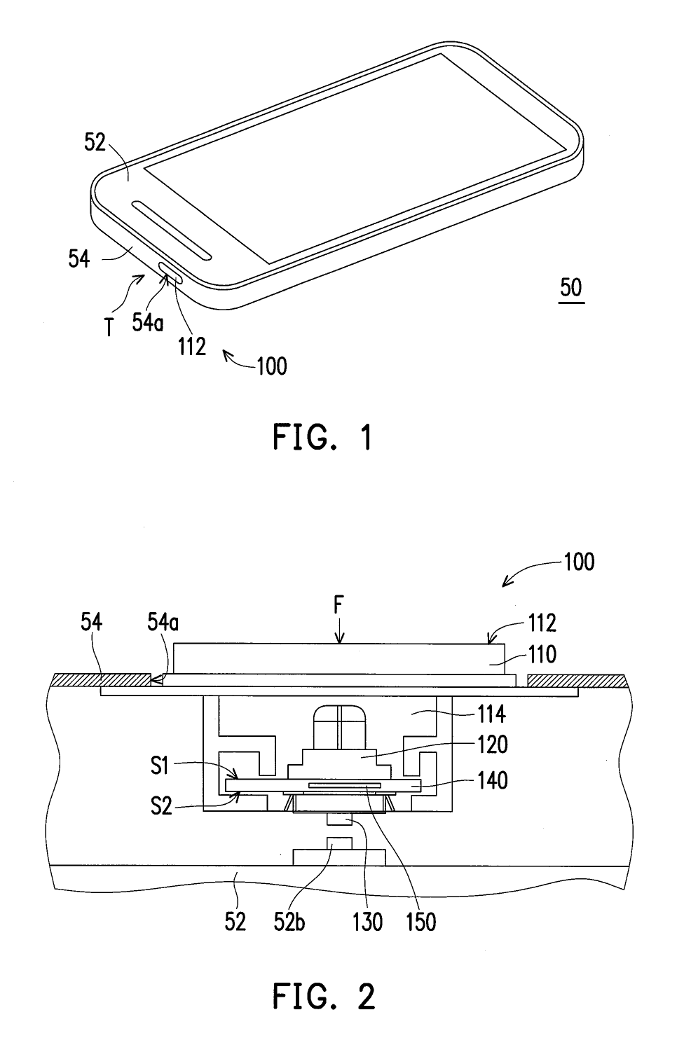

FIG. 1 is a schematic view of a handheld electronic device according to an embodiment of the invention. Referring to FIG. 1, in the present embodiment, the handheld electronic device 50 includes a body 52, a housing 54 and a button assembly 100. The housing 54 covers the body 52 and has an opening 54a, and the button assembly 100 is suitable for being disposed at the opening 54a. The handheld electronic device 50 is, for example, a mobile phone or a smart phone, the housing 54 is, for example, a casing of the mobile phone or the smart phone, and the opening 54 is, for example, located at a top portion T of the housing 54, but the present invention does not limit the type of the handheld electronic device 50, and neither does the invention limit the location of the opening 54 on the housing 54.

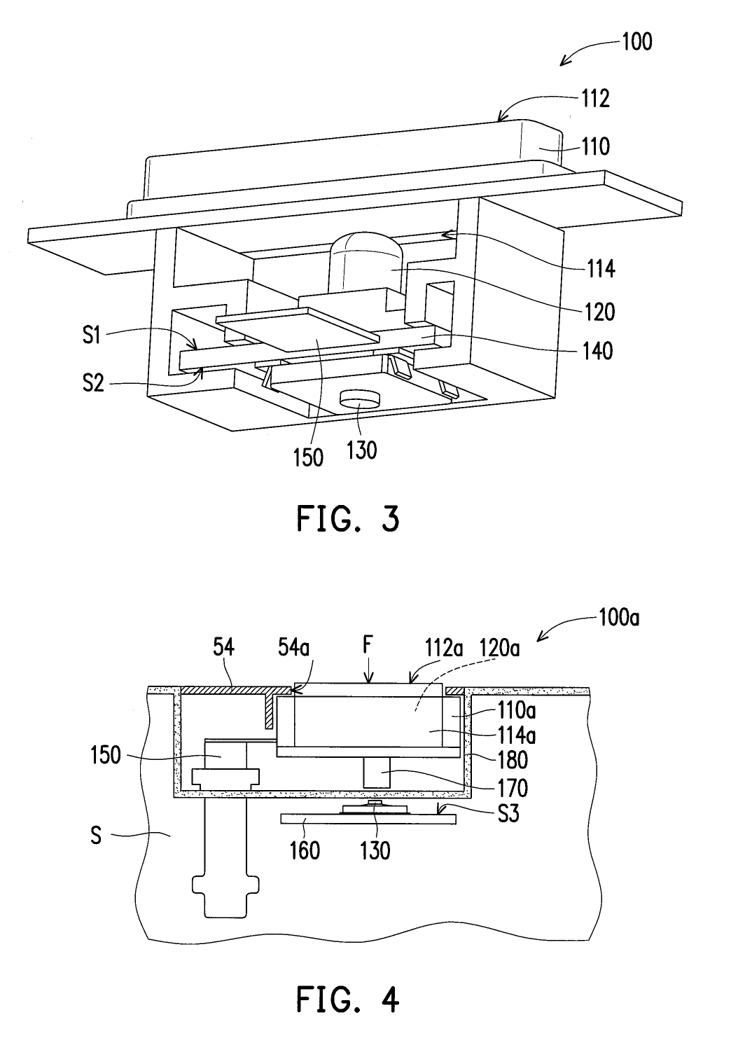

FIG. 2 is a partially enlarged view illustrating the handheld electronic device in FIG. 1. FIG. 3 is a schematic view illustrating the button assembly in FIG. 1. Referring to FIG. 1 to FIG. 3, in the present embodiment, the button assembly 100 includes a button 110, a signal-receiving-and-transmitting component 120 and a switch 130. The button 110 is movably disposed at the opening 54a, and the button 110 has a pressing portion 112 exposed by the housing 54. The switch 130 is disposed in the housing 54 and coupled to the button 110, so that the switch 130 is adapted to be actuated by pressing the pressing portion 112 of the button 110. The button 110 is, for example, a power key button, the switch 130 is, for example, a power key switch, but the present invention is not limited thereto.

On the other hand, the signal-receiving-and-transmitting component 120 is disposed in the housing 54 and corresponds to the pressing portion 112, wherein the signal-receiving-and-transmitting component 120 is suitable for transmitting or receiving a wireless signal passing through the pressing portion 112. In the present embodiment, the signal-receiving-and-transmitting component 120 is an infrared-receiving-and-transmitting component, and the wireless signal is an infrared signal. In addition, the signal-receiving-and-transmitting component 120 of the present embodiment is an integral component having both functions of receiving and transmitting, but in other embodiment, the signal-receiving-and-transmitting component 120 may include a signal-receiving component and a signal-transmitting component independent from each other. The present invention does not limit the formation and type of the signal-receiving-and-transmitting component 120. Therefore, the signal-receiving-and-transmitting component 120 is suitable for receiving and transmitting the infrared signal, such that the handheld electronic device 50 having the signal-receiving-and-transmitting component 120 may control the electronic products at home. For example, household appliances such as televisions, air conditionings and home theaters, etc., generally are controlled by the corresponding remote controls through the infrared signal. Therefore, by disposing the signal-receiving-and-transmitting component 120 in the housing 54 of the handheld electronic device 50, and by integrating the functions of the remote controls a user may need, for example, in software format, into the handheld electronic device 50, the handheld electronic device 50 may control the household appliances by the signal-receiving-and-transmitting component 120 to replace all kinds of conventional remote controls, so as to enhance convenience and practicability of the handheld electronic device 50.

To be more specific, referring to FIG. 2 and FIG. 3, in the present embodiment, the button assembly 100 further includes a first circuit board 140. The button 110 has a containing space 114. The first circuit board 140 is disposed in the containing space 114 and located in the housing 54. The signal-receiving-and-transmitting component 120 is disposed on a first surface S1 of the first circuit board 140, and the first surface S1 faces the pressing portion 112, such that the signal-receiving-and-transmitting component 120 faces the pressing portion 112 to transmit or receive a wireless signal.

On the other hand, in the present embodiment, the switch 130 is disposed on a second surface S2 of the first circuit board 140. The second surface S2 is opposite to the first surface S1, and the button 110 exposes the switch 130. In other words, the first surface S1 faces the pressing portion 112 and faces outside the housing 54. The second surface S2 and the switch 130 faces inside the housing, and the first circuit board 140 disposed in the containing space 114, both the signal-receiving-and-transmitting component 120 and the switch 130 disposed on the circuit board 140 move along with the button 110.

In addition, the switch 130 corresponds to a protrusion 52b, wherein the protrusion 52b is disposed in the housing 54 and faces the opening 54a. Specifically, the protrusion 52b is disposed on the body 52 in the housing 54 and faces the opening 54a, such that the switch 130 inside the housing corresponds to the protrusion 52b facing the opening 54a. Thus, the user may apply external force F to the button 110 by pressing the pressing portion 112 exposed by the housing 54, so as to drive the switch 130 exposed by the button 110 to move toward the inside of the housing 54, such that the switch 130 is actuated by leaning against the protrusion 52b facing the opening 54a. However, in other embodiment, the protrusion 52b may be disposed on the side wall (not shown) of the housing 54 and corresponds to the switch 130. Moreover, the switch 130 may also be actuated by leaning against other component similar to the protrusion 52b or directly leaning against the body 52 or the housing 54. The present invention does not limit the actuating method of the switch 130.

In the present embodiment, the first circuit board 140 is, for example, a printed circuit board (PCB) or a flexible printed circuit (FPC) board, but the present invention is not limited thereto. In addition, the first circuit board 140 is connected to a flexible printed circuit (FPC) board 150 located in the housing 54. The FPC board 150 is connected to the first circuit board 140 and the body 52, such that the first circuit board 140, the signal-receiving-and-transmitting component 120 disposed thereon and the switch 130 is electrically connected to the body 52. Therefore, when the signal-receiving-and-transmitting component 120 transmits and receives a wireless signal or the switch 130 is actuated, the body 52 of the handheld electronic device 50 may execute corresponding operations.

Thus, the button 110 is adapted to be disposed on one opening 54a of the housing 54 of the handheld electronic device 50, the signal-receiving-and-transmitting component 120 is capable of transmitting or receiving the wireless signal passing through the pressing portion 112, and the switch 130 is actuated by pressing the pressing portion 112 of the button 110. Accordingly, the button assembly 100 is suitable for a handheld electronic device 50 with fewer openings so as to reduce the amount of the openings located on the housing 54 of the handheld electronic device 50.

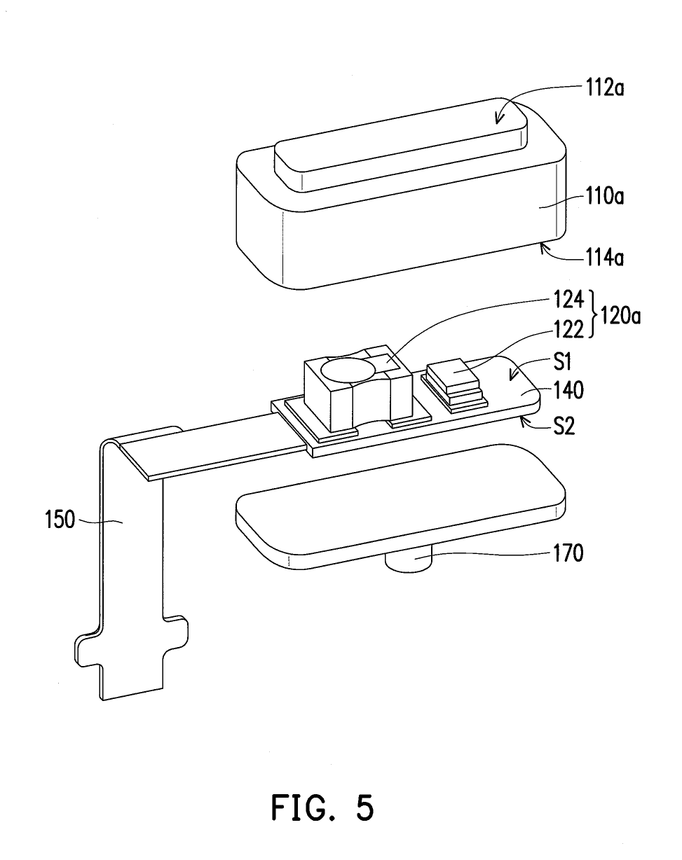

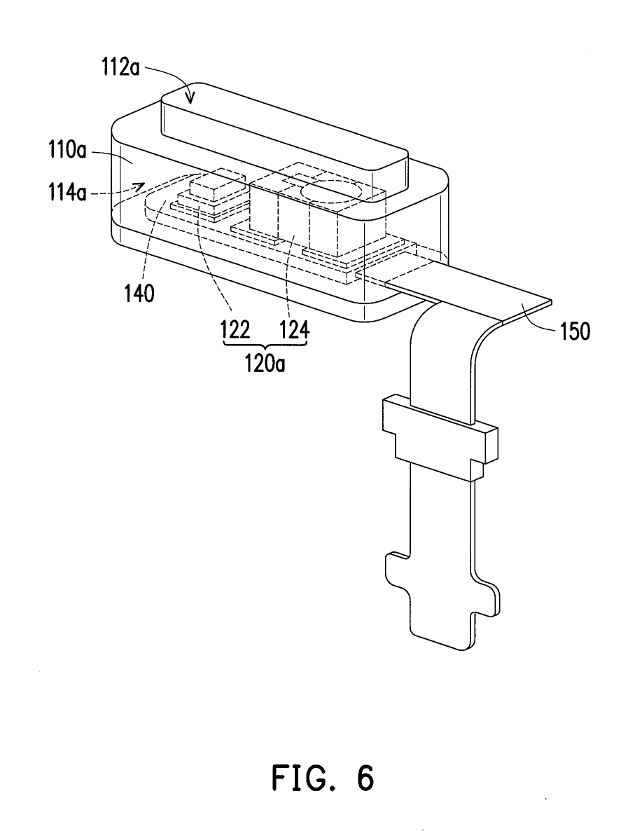

FIG. 4 is a partially enlarged view illustrating a handheld electronic device according to another embodiment of the present invention. FIG. 5 is an exploded view illustrating the button in FIG. 4. FIG. 6 is a schematic view illustrating the button in FIG. 5. Referring to FIG. 4 to FIG. 6, in the present embodiment, the button assembly 100a is also suitable for being disposed at an opening 54a. The button assembling 100a includes a button 110a, a signal-receiving-and-transmitting component 120a and a switch 130. Part of the components and the operative method of the button assembly 100a are different from the button assembly 100. The same reference numbers are used to refer to the components having similar functions and operative methods in the present embodiment and the foregoing embodiments, and the relevant description can be referred to the foregoing embodiments. The difference between the present embodiment and the foregoing embodiments will be described as follows.

In the present embodiment, the button 110a is movably disposed at the opening 54a, and the button 110a has a pressing portion 112a exposed by the housing 54. The button 110a has a containing space 114a, wherein the containing space 114a is sealed, and a first circuit board 140 and a signal-receiving-and-transmitting component 120a is located in the containing space 114a so as to be located in the housing 54. The signal-receiving-and-transmitting component 120a is disposed on a first surface S1 of the first circuit board 140, and the first surface S1 faces a pressing portion 112a, such that the signal-receiving-and-transmitting component 120a faces the pressing portion 112a for transmitting or receiving a wireless signal.

In the present embodiment, the signal-receiving-and-transmitting component 120a is an infrared-receiving-and-transmitting component, and the wireless signal is an infrared signal. In addition, the signal-receiving-and-transmitting component 120a includes a signal-receiving component 122 and a signal-transmitting component 124 independent from each other, but in other embodiments, the signal-receiving-and-transmitting component 120a may be an integral component having both receiving and transmitting functions. The present invention does not limit the formation and the type of the signal-receiving-and-transmitting component 120a.

Referring to FIG. 5 and FIG. 6, in the present embodiment, the first circuit board 140 located in the sealed containing space 114a is connected to a FPC board 150 located in the housing 54. The FPC board 150 is connected to the first circuit board 140 and extended to the outside of the button 110a so as to be connected to the body 52, such that the first circuit board 140 and the signal-receiving-and-transmitting component 120a disposed thereon are electrically connected to the body 52, but the FPC board 150 extended to the outside of the button 110a does not affect the sealing tightness of the containing space 114a. Accordingly, when the signal-receiving-and-transmitting component 120a transmits or receives the wireless signal, the body 52 of the handheld electronic device 50 may execute corresponding operations.

On the other hand, referring to FIG. 4, in the present embodiment, the button assembly 100a further includes a second circuit board 160. The second circuit board 160 is disposed in the housing 54, and the switch 130 is disposed on a third surface S3 of the second circuit board 160, wherein the third surface S3 faces the button 110a. Moreover, the button assembly 100a further includes a protrusion 170 disposed on a surface of the button 110a inside the housing 54 and corresponding to the switch 130. The protrusion 170 disposed on the surface of the button 110a inside the housing 54 moves along with the button 110a.

Thus, a user may apply external force F to the button 110a by pressing the pressing portion 112a exposed by the housing 54, so as to drive the protrusion 170 leaning against the switch 130, such that the switch 130 is actuated. In addition, the second circuit board 160 is connected to the body 52, such that the second circuit board 160 and the switch 130 disposed thereon are electrically connected to the body 52. When the switch 130 is actuated, the body 52 of the handheld electronic device 50 may execute the corresponding operations.

On the other hand, in the present embodiment, the button assembly 100a further includes a waterproof material. The waterproof material 180 is disposed at the opening 54a and isolates the button 110a and an inner space S of the housing 54. The button 110a and the switch 130 are respectively located at the two opposing sides of the waterproof material 180. The FPC board 150 is extended to the outside of the waterproof material and connected to the body 52, but does not affect the isolation property of the waterproof material. The waterproof material is, for example, rubber, but the present invention is not limited thereto. Thus, the waterproof material 180 may provides the inner space S of the housing 54 with waterproof function by isolating the button 110a, also, the waterproof material 180 is soft and does not affect the contact of the protrusion 170 and the switch 130 respectively located at the two opposing sides of the waterproof material.

Accordingly, the button 110a may be disposed at one opening 54a of the housing 54 of the handheld electronic device 50, the signal-receiving-and-transmitting component 120a is capable of transmitting or receiving the wireless signal passing through the pressing portion 112a, and the switch 130 is actuated by pressing the pressing portion 112a of the button 110. Thereby, the button assembly 100a is suitable for the handheld electronic device 50 with fewer openings, so as to reduce the amount of the openings located on the housing 54 of the handheld electronic device 50.

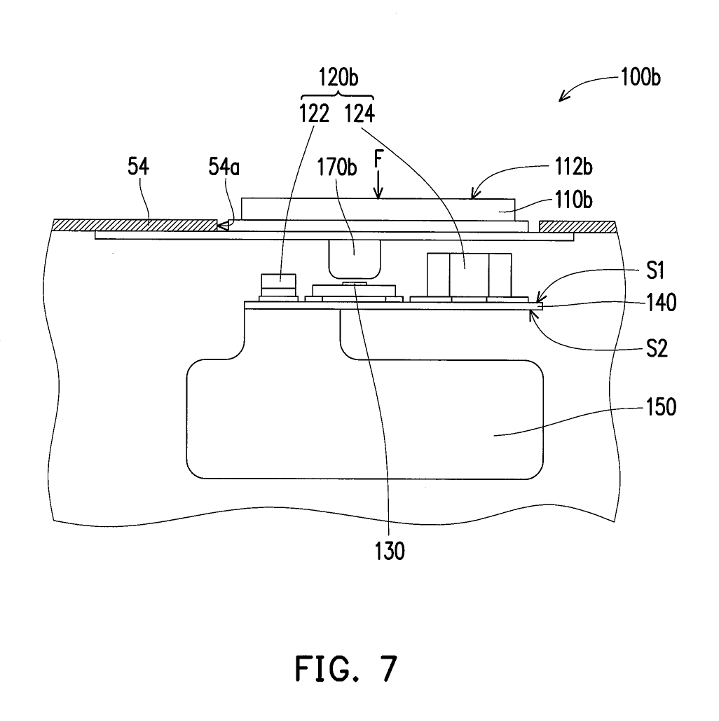

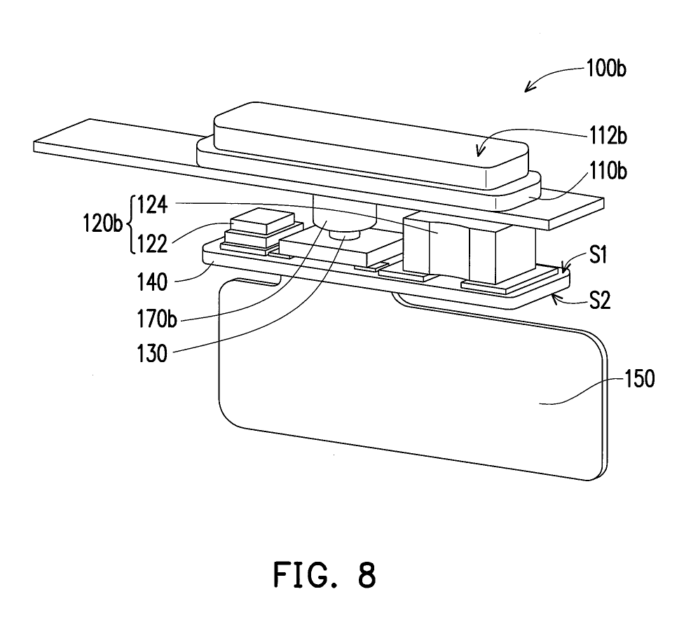

FIG. 7 is a partially enlarged view illustrating a handheld electronic device according to yet another embodiment of the present invention. FIG. 8 is a schematic view of the button assembly in FIG. 7. Referring to FIG. 7 and FIG. 8, in the present embodiment, the button assembly 100b is also suitable for being disposed at the opening 54a. The button assembly 100b includes a button 110b, a signal-receiving-and-transmitting component 120b and a switch 130. Part of the components and the operative methods of the button assembly 100b are different from the button assembly 100 and the button assembly 100a. The same reference numbers are used to refer to the components having similar functions and operative methods in the present embodiment and the foregoing embodiments, and a relevant description can be referred to the foregoing embodiments. The difference between the present embodiment and the foregoing embodiments will be described as follows.

In the present embodiment, the button 110b is movably disposed at the opening 54a, and the button 110b has a pressing portion 112b exposed by the housing 54, but the button 110b does not have a containing space. Therefore, the first circuit board 140 is located outside of the button 110b, and the signal-receiving-and-transmitting component 120b and the switch 130 are together disposed at the first surface S1 of the first circuit board 140. The first surface S1 faces the pressing portion 112b, such that the signal-receiving-and-transmitting component 120b faces the pressing portion 112b for transmitting or receiving a wireless signal.

In addition, in the present embodiment, the signal-receiving-and-transmitting component 120b is an infrared-receiving-and-transmitting component and includes a signal-receiving component 122 and a signal-transmitting component 124 independent from each other, and the switch 130 is located between the signal-receiving component 122 and the signal-transmitting component 124. However, in other embodiments, the switch 130 may be disposed at one side of the signal-receiving component 122 or the signal-transmitting component 124, and the signal-receiving-and-transmitting component 120b may be an integral component having both receiving and transmitting functions. The present invention does not limit the location of the switch 130 on the first surface S1, also does not limit the formation and the type of the signal-receiving-and-transmitting component 120b.

On the other hand, in the present embodiment, the button assembly 100b further includes a protrusion 170b disposed on a surface of the button 110b inside the housing 54 and corresponding to the switch 130. The protrusion 170b disposed on the surface of the button 110b inside the housing 54 moves along with the button 110b. Thus, a user may apply external force F to the button 110b by pressing the pressing portion 112b exposed by the housing 54, so as to drive the protrusion 170b leaning against the switch 130, such that the switch 130 is actuated.

In addition, the first circuit board 140 is connected to the FPC board 150 located inside the housing 54. The FPC board 150 is connected to the second surface S2 of the first circuit board 140 and the body 52, such that the switch, the first circuit board 140 and the signal-receiving-and-transmitting component 120b disposed thereon are electrically connected to the body 52. Thus, when the signal-receiving-and-transmitting component 120b transmits or receives the wireless signal, or the switch 130 is actuated, the body 52 of the handheld electronic device 50 may execute the corresponding operations.

Accordingly, the button 110b may be disposed at one opening 54a of the housing 54 of the handheld electronic device 50, the signal-receiving-and-transmitting component 120b is capable of transmitting or receiving the wireless signal passing through the pressing portion 112b, and the switch 130 is actuated by pressing the pressing portion 112b of the button 110. Thereby, the button assembly 100b is suitable for the handheld electronic device 50 with fewer openings, so as to reduce the amount of the openings located on the housing 54 of the handheld electronic device 50.

In sum, the present invention provides a button assembly and the handheld electronic device using the same, wherein the button is movably disposed at the opening. The signal-receiving-and-transmitting component and the switch are disposed inside the housing of the handheld electronic device, wherein the signal-receiving-and-transmitting component corresponds to a pressing portion of the button and the switch is coupled to the button. Accordingly, the button may be disposed at one opening of the housing of the handheld electronic device, the signal-receiving-and-transmitting component is capable of transmitting or receiving a wireless signal passing through the pressing portion, and the switch is actuated by pressing the pressing portion of the button. Thereby, the button assembly is suitable for the handheld electronic device with fewer openings, so as to reduce the amount of the openings located on the housing of the handheld electronic device.

It will be apparent to those skilled in the art that various modifications and variations can be made to the structure of the disclosure without departing from the scope or spirit of the invention. In view of the foregoing, it is intended that the disclosure cover modifications and variations of this invention provided they fall within the scope of the following claims and their equivalents.

What is claimed is:

1. A button assembly, suitable for being disposed at an opening of a housing of a handheld electronic device, the button assembly comprising:
a button, movably disposed at the opening, and the button having a pressing portion exposed by the housing;
a signal-receiving-and-transmitting component, disposed in the housing and corresponding to the pressing portion, wherein the signal-receiving-and-transmitting component is suitable for transmitting or receiving a wireless signal passing through the pressing portion; and
a switch, disposed in the housing and coupled to the button, such that the switch is adapted to be actuated by pressing the pressing portion of the button.

2. The button assembly as claimed in claim 1, wherein the signal-receiving-and-transmitting component comprises an infrared-receiving-and-transmitting component.

3. The button assembly as claimed in claim 1, further comprising:
a first circuit board, disposed in the housing, wherein the signal-receiving-and-transmitting component is disposed on a first surface of the first circuit board.

4. The button assembly as claimed in claim 3, wherein the button has a containing space, the first circuit board is disposed in the containing space, and the first surface faces the pressing portion.

5. The button assembly as claimed in claim 4, wherein the switch is disposed on a second surface of the first circuit board, the second surface is opposite to the first surface, and the button exposes the switch.

6. The button assembly as claimed in claim 5, wherein the switch corresponds to a protrusion, and the protrusion is disposed in the housing and faces the opening.

7. The button assembly as claimed in claim 4, further comprising:
a second circuit board, disposed in the housing, wherein the switch disposed on a third surface of the second circuit board, and the third surface faces the button.

8. The button assembly as claimed in claim 7, further comprising:
a protrusion, disposed on a surface of the button inside the housing and corresponding to the switch.

9. The button assembly as claimed in claim 7, wherein the containing space is sealed, and the first circuit board and the signal-receiving-and-transmitting component are disposed in the containing space.

10. The button assembly as claimed in claim 9, further comprising:
a waterproof material, disposed at the opening and isolating the button and an inner space of the housing, wherein the button and the switch are respectively located at two opposing sides of the waterproof material.

11. The button assembly as claimed in claim 3, wherein the first circuit board is located outside of the button, and the signal-receiving-and-transmitting component and the switch are disposed on the first surface of the first circuit board.

12. The button assembly as claimed in claim 11, further comprising:
a protrusion, disposed on a surface of the button inside the housing and corresponding to the switch.

13. A handheld electronic device, comprising:
a body;
a housing, covering the body and having an opening; and
a button assembly, disposed at the opening, the button assembly comprising:
a button, movably disposed at the opening, and having a pressing portion exposed by the housing;
a signal-receiving-and-transmitting component, disposed in the housing and corresponding to the pressing portion, wherein the signal-receiving-and-transmitting component is suitable for transmitting or receiving a wireless signal passing through the pressing portion; and
a switch, disposed in the housing and coupled to the button, such that the switch is adapted to be actuated by pressing the pressing portion of the button.

14. The handheld electronic device as claimed in claim 13, wherein the signal-receiving-and-transmitting component comprises an infrared-receiving-and-transmitting component.

15. The handheld electronic device as claimed in claim 13, wherein the button assembly further comprises a first circuit board disposed in the housing, and the signal-receiving-and-transmitting component is disposed on a first surface of the first circuit board.

16. The handheld electronic device as claimed in claim 15, wherein the button has a containing space, the first circuit board is disposed in the containing space, and the first surface faces the pressing portion.

17. The handheld electronic device as claimed in claim 16, wherein the switch is disposed on a second surface of the first circuit board, the second surface is opposite to the first surface, and the button exposes the switch.

18. The handheld electronic device as claimed in claim 17, wherein the switch corresponds to a protrusion, and the protrusion is disposed in the housing and faces the opening.

19. The handheld electronic device as claimed in claim 16, wherein the button assembly further comprises a second circuit board disposed in the housing, the switch is disposed on a third surface of the second circuit board, and the third surface faces the button.

20. The handheld electronic device as claimed in claim 19, wherein the button assembly further comprises a protrusion, disposed on a surface of the button inside the housing and corresponding to the switch.

21. The handheld electronic device as claimed in claim 19, wherein the containing space is sealed, and the first circuit board and the signal-receiving-and-transmitting component are disposed in the containing space.

22. The handheld electronic device as claimed in claim 21, wherein the button assembly further comprises a waterproof material disposed at the opening and isolating the button and an inner space of the housing, and the button and the switch are respectively located at two opposing sides of the waterproof material.

23. The handheld electronic device as claimed in claim 15, wherein the first circuit board is located outside of the button, and the signal-receiving-and-transmitting component and the switch are disposed on the first surface of the first circuit board.

24. The handheld electronic device as claimed in claim 23, wherein the button assembly further comprises a protrusion, disposed on a surface of the button inside the housing and corresponding to the switch.
